(19) United States
(12) Patent Application Publication
(10) Pub. No.: US 2015/0012574 A1
(43) Pub. Date: Jan. 8, 2015

(54) Model calculation unit and control unit for calculating a data-based function model having data in various number formats

(71) Applicants: Wolfgang Fischer, Gerlingen (DE); Nico Bannow, Stuttgart (DE); Andre Gunturo, Pforzheim (DE)

(72) Inventors: Wolfgang Fischer, Gerlingen (DE); Nico Bannow, Stuttgart (DE); Andre Gunturo, Pforzheim (DE)

(73) Assignee: Robert Bosch GmbH, Stuttgart (DE)

(21) Appl. No.: 14/320,941

(22) Filed: Jul. 1, 2014

(30) Foreign Application Priority Data
Jul. 2, 2013 (DE) 10 2013 212 840.1

(51) Int. Cl. H03M 7/14; H03M 7/24

(52) U.S. Cl. CPC H03M 7/14; H03M 7/24
USPC 708/105

(57) ABSTRACT

A model calculation unit for calculating a data-based function model, in particular a Gaussian process model, in a control unit, including: a processor core to carry out a strictly hardware-based calculation of an algorithm for a data-based function model, the data-based function model being calculated using provided calculation data, in particular hyperparameters and node data; and a strictly hardware-based conversion unit to provide the processor core with at least a portion of the calculation data, in particular the provided node data, in a predefined number format.

### RELATED APPLICATION INFORMATION

The present application claims priority to and the benefit of German patent application no. 10 2013 212 840.1, which was filed in Germany on Jul. 2, 2013, the disclosure of which is incorporated herein by reference.

### FIELD OF THE INVENTION

The present invention relates to model calculation units for control units, in particular hardwired model calculation units as hardware units, in which or with the aid of which data-based function models may be calculated, in particular for controlling engine systems. The present application also relates to the provision and processing of configuration data of data-based function models in such model calculation units.

### BACKGROUND INFORMATION

Control units having a main processing unit and a separate model calculation unit for calculating data-based function models are known from the related art. The publication DE 10 2010 028 266 A1, for example, discusses a control unit having an additional logic circuit as a model calculation unit. The additional logic circuit is configured on the hardware side for calculating exponential functions and sum functions. This makes it possible to support in a hardware unit Bayesian regression methods which are required in particular for calculating Gaussian process models.

The model calculation unit is configured to carry out mathematical processes for calculating the data-based function model based on parameters/hyperparameters and node or training data. In particular, the model calculation unit is configured on the hardware side for efficiently calculating exponential functions to thereby enable calculation of Gaussian process models at a higher computation rate than is possible in the main processing unit using suitable software.

In general, configuration data which contain parameters and nodes for calculating the data-based function model are provided for calculation in the model calculation unit, and the calculations based on the configuration data are carried out by the hardware of the model calculation unit.

The node data are generally predefined as floating point data or fixed point data. When implementing in hardware, however, the algorithms which are based on floating point arithmetic must be implemented separately from the algorithms which are based on fixed point arithmetic.

The publication U.S. Pat. No. 4,675,809 discusses the use of various floating point data types in a system by employing a conversion unit.

The publication U.S. Pat. No. 5,161,117 discusses a method for utilizing various floating point values having various bases.

### SUMMARY OF THE INVENTION

Provided according to the present invention are the hardware model calculation unit as described herein and the control unit including a model calculation unit as described herein.

Additional advantageous embodiments of the present invention are specified in the further descriptions herein.

According to one first aspect, a model calculation unit for calculating a data-based function model, in particular a Gaussian process model, is provided in a control unit, including:
a processor core configured to carry out a strictly hardware-based calculation of an algorithm for a data-based function model, the data-based function model being calculated using provided calculation data, in particular hyperparameters and node data; and
a strictly hardware-based conversion unit which is configured to provide the processor core with at least a portion of the provided calculation data, in particular node data, in a predefined number format.

In addition to a software-controlled main processing unit, the control units described at the outset include a model calculation unit implemented in hardware, which along with an exponential function calculation unit also include hardware logic for calculating sums in at least one loop. The calculation resorts to predefined calculation data, for Gaussian process models, parameters and node data in particular, which are stored in a memory area accessible for the model calculation unit.

In the configuration of the model calculation unit, the hardware blocks are generally configured in such a way that calculations may be calculated with the values of the maximally occurring bit resolution. In conventional control units, this corresponds, for example, to a 32-bit resolution in floating point number format.

The calculation data are generally predefined in the form of floating point data or fixed point data. When implementing in hardware, however, the algorithms which are based on floating point arithmetic must be implemented separately from the algorithms which are based on fixed point arithmetic. In order, however, to limit the space requirements for an integrated configuration of the hardware of the model calculation unit, only the processing of the calculation data is provided in a number format. If calculation data are wholly or partially present in another number format, then a preprocessing for the relevant calculation data must be provided in order to render these in the desired number format, i.e., either in a fixed point number format a or floating point number format.

While it is sufficient for calculating data-based function models that the calculation data are provided, for example, with an accuracy of 8 bits or 16 bits as fixed point or floating point values, floating point calculations take place in the main processing unit generally with 32-bit wide floating point values.

In order to minimize the memory requirements for providing calculation data and still provide a model calculation unit having an option for calculating calculation data with great accuracy, a model calculation unit may therefore be provided which includes a conversion unit as an input stage. With the conversion unit it is possible to directly provide the model calculation unit with other number formats of calculation data for the calculation such as, for example, values in 16-bit floating point number format or values in 16-bit fixed point number format, and to use these there without providing a separate hardware in the model calculation unit.

The conversion unit also makes it possible for a conversion of the data necessary for the calculation not to have to be carried out in the main processing unit, the capacity of which is normally limited in control units. Sensor data which are normally provided as fixed point values may also be suitably converted on the fly in the conversion unit, i.e., without intervention from the main processing unit, with the aid of a provided shared exponential parameter.

The conversion unit may also be configured to carry out, as a function of a selection signal, a conversion of provided calculation data of a number format which differs from the predefined number format into the predefined number format.

According to one specific embodiment, the conversion unit may include at least one conversion block for converting data of a first number format into data of the predefined number format, as well as a multiplexer, in order, as a function of the selection signal, to forward to the processor core either the provided calculation data or the calculation data converted by one of the at least one conversion blocks into the predefined number format.

It may be provided that the predefined number format corresponds to a 32-bit floating point number format.

In particular, a first conversion block may be configured to convert data from a floating point number format, which has a bit number lower than the predefined number format, into the predefined number format.

A second conversion block may be configured to convert data from a fixed point number format into the predefined number format.

The second conversion block may also be configured to take into account a predefined exponent value when converting data from the fixed point number format into the predefined number format.

According to another aspect, a control unit is provided, in particular, structurally integrated, for example, in the form of a chip. The control unit includes:
a main processing unit for software-controlled execution of functions;
a memory unit for storing calculation data in at least one number format; and
the above-mentioned model calculation unit.

In addition, the main processing unit may provide a selection signal to the model calculation unit as a function of the number format in which the calculation data are stored in the memory unit, so that as a function of the selection signal, the conversion unit carries out a conversion of the calculation data into the predefined number format.

Specific embodiments of the present invention are explained in greater detail below with reference to the appended drawings.

### BRIEF DESCRIPTION OF THE DRAWINGS

FIG. 1 shows a schematic representation of a control unit including a main processing unit and a model calculation unit.

FIG. 2 shows a schematic representation of the model calculation unit of FIG. 1 having a conversion unit.

FIG. 3 shows a detailed representation of the conversion unit of FIG. 2.

FIG. 4 shows a representation of a conversion from a 16-bit fixed point value having a shared exponent into a value in floating point number format.

### DETAILED DESCRIPTION

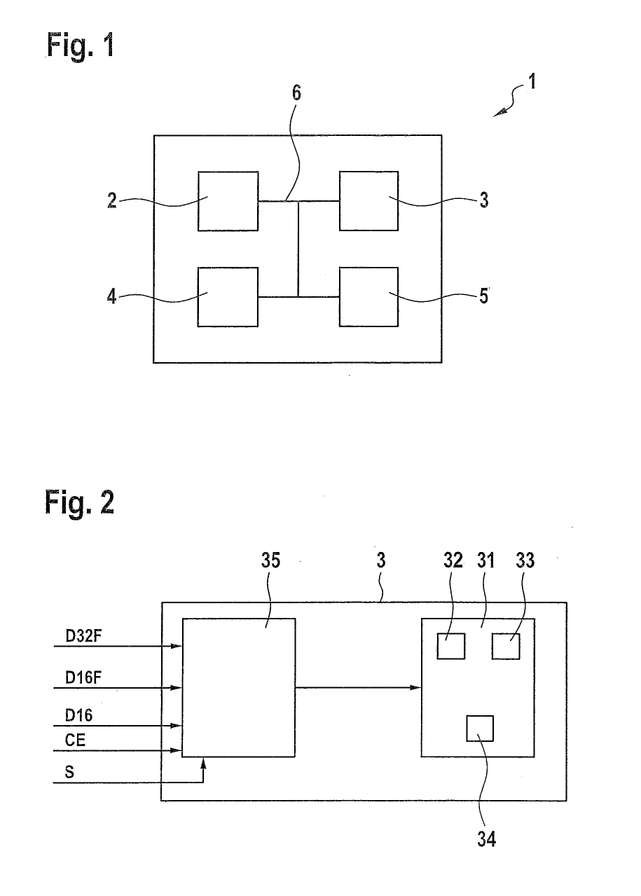

FIG. 1 shows a schematic representation of a hardware architecture for an integrated control unit 1 in which a main processing unit 2, for example, in the form of a microcontroller, as well as a model calculation unit 3 for hardware-based calculation of a, in particular data-based function model are provided in an integrated manner (for example, monolithic). Main processing unit 2 and model calculation unit 3 communicate with each other via a system bus 6. Model calculation unit 3 is configured exclusively as hardware (hardwired) and is therefore unable to execute any software code. For this reason, no processor or the like is provided in model calculation unit 3 either. This makes possible a resource-optimized implementation of such a model calculation unit 3.

Control unit 1 also includes an internal memory unit 4 and a DMA unit 5 (DMA—direct memory access) which is connected to main processing unit 2 and model calculation unit 3 via an internal communication link 6 such as, for example, an internal data bus.

In FIG. 2, model calculation unit 3 is shown in detail. It is apparent that a processor core 31 having an exponential unit 32, an addition and multiplication unit 33 which in some cases may be provided in combination in a shared FMA unit (FMA=fused multiply add), in addition to a logic unit 34 for providing a fixed computation sequence using aforementioned units 32, 33, is provided for calculating a data-based function model.

In general, two IEEE-754 floating point standards as a data format are known. The floating point standards correspond in the case of simple accuracy to a 32-bit resolution, i.e., one sign-bit, 8 exponent bits and 23 mantissa bits, and in the case of half the accuracy to a 16-bit resolution, i.e. one sign-bit,

5 exponent bits and 10 mantissa bits. Moreover, in the case of a 16-bit fixed point number format, 16-bit values are used to represent a data value without the provision of an exponent.

In addition to the 16-bit fixed point number format, a shared exponent for a series of data values may be provided, so that the data are assigned a common order of magnitude.

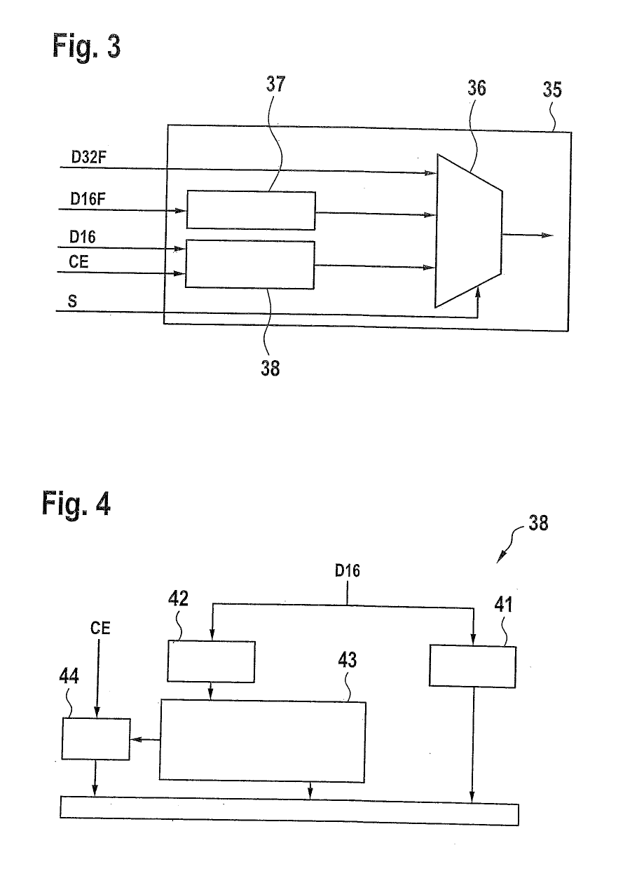

To enable model calculation unit 3 to use data values having different data formats, a conversion unit 35 is provided in model calculation unit 3, as is shown in greater detail in conjunction with FIG. 3. Conversion unit 35 converts calculation data, i.e., for example, the node data, into a predefined number format such as, for example, into a 32-bit floating point number format, and provides this to the hardware which reproduces the calculation algorithm, in model calculation unit 3 as processing data V. The data elements of the calculation data may also be present in various number formats, so that the calculation data are correspondingly converted to the number format of the data elements.

Conversion unit 35 includes a multiplexer 36 for providing converted processing data V for calculating the data-based function model in model calculation unit 3. In the present case, the node data of model calculation unit 3 may be provided as data D32F in the form of a 32-bit floating point number format (floating point format with simple accuracy), data D16F in the form of a 16-bit floating point number format (floating point number format with half accuracy) or data D16 in the form of a 16-bit fixed point number format in conjunction with a predefined shared exponent CE.

Data D16F in the 16-bit floating point number format and data D16 in the 16-bit fixed point number format are converted in a known manner in corresponding first and second conversion blocks 37, 38 into a 32-bit floating point number format, and together with data D32F in 32-bit floating point number format which do not have to be converted, are fed to multiplexer 36. Accordingly, one of data formats D16F, D32F, D16 is selected in multiplexer 36 with the aid of a selection signal S which, for example, may be provided by main processing unit 2.

The conversion from the 16-bit floating point number format into the 32-bit floating point number format in first conversion block 37 is a simple bit operation. The 5 bits for the exponent which are interpreted as signed ±15 (excess−15), and the 32-bit floating point number format which uses 8 bits for the exponent which are interpreted as signed ±127 (excess−127), result in an exponent conversion by an addition of 112 (i.e., 127−15), which typically in an integrated configuration may be implemented in a space-efficient manner as a multiplexer having two inputs, which is controlled by the highest exponent bit, a zero value, an indication for +∞ or −∞, and NaN (not-a-number) being treated as special cases, so that the conversion result yields the same value. The expansion of the mantissa values from 10 bits to 23 bits uses a simple insertion of zeroes as the lowest-order bits, which may be achieved, for example, by a left shift operation by 13 digits or a concatenation having 10 mantissa bits and 13 zero bits.

The conversion from a 16-bit fixed point number format into a 32-bit floating point number format may be implemented, for example, with the aid of second conversion block 38 shown in FIG. 4. At the same time predefined shared exponent CE may be taken into account. Second conversion block 38 of FIG. 4 makes it possible to generate a 32-bit floating point value from a signed 16-bit fixed point number format.

In the process, the sign-bit of the input value is extracted in a sign extraction block 41 and is used as the sign-bit for the output value. In addition, the sign-bit is extracted in a value extraction block 42 from the input value and subsequently shifted to the left in a normalization block 43 by a bit shift operation until the highest value bit corresponds to “1,” a zero value of the input value being treated as a special case, so that the conversion result also yields zero. Normalization block 43 supplies an indication of a number of the required bit shifts to an exponent addition unit 44, which subtracts the number of bit shifts from the value of the shared exponent and provides this as the exponent value of the 32-bit floating point value as the conversion result. The conversion result is produced by combining the mantissa value obtained in normalization block 43, the sign-bit extracted in sign extraction block 41 and the exponent value obtained in exponent addition unit 44. The conversion result is then provided to model calculation unit 3 as processing data V which contains the converted node data.

What is claimed is:

1. A model calculation unit for calculating a data-based function model in a control unit, comprising:
a processor core configured to carry out a strictly hardware-based calculation of an algorithm for a data-based function model, the data-based function model being calculated using provided calculation data; and
a strictly hardware-based conversion unit configured to provide the processor core with at least a portion of the calculation data in a predefined number format.

2. The model calculation unit of claim 1, wherein the conversion unit is configured to carry out, as a function of a selection signal, a conversion of at least a portion of the provided calculation data of one number format which differs from the predefined number format, into the predefined number format.

3. The model calculation unit of claim 1, wherein the conversion unit includes at least one conversion block for converting a first number format of data into the predefined number format, as well as a multiplexer, in order, as a function of the selection signal, to forward to the processor core either the provided calculation data or the calculation data converted by one of the at least one conversion blocks into the predefined number format.

4. The model calculation unit of claim 3, wherein the predefined number format corresponds to a 32-bit floating point number format.

5. The model calculation unit of claim 3, wherein a first conversion block is configured to convert data from a floating point number format which includes a bit number lower than the predefined number format, into the predefined number format.

6. The model calculation unit of claim 3, wherein a second conversion block is configured to convert data from a fixed point number format into the predefined number format.

7. The model calculation unit of claim 6, wherein the second conversion block is configured to take into account a predefined exponent value when converting data from the fixed point number format into the predefined number format.

8. The model calculation unit of claim 1, wherein the data-based function model include a Gaussian process model.

9. The model calculation unit of claim 1, wherein the calculation data includes hyperparameters and node data.

10. The model calculation unit of claim 1, wherein the at least a portion of the calculation data includes node data.

11. The model calculation unit of claim 1, wherein the calculation data includes hyperparameters and node data, and wherein the at least a portion of the calculation data includes the node data.

12. The model calculation unit of claim 1, wherein the data-based function model include a Gaussian process model, wherein the calculation data includes hyperparameters and node data, and wherein the at least a portion of the calculation data includes the node data.

13. A control unit, comnprising:
a main processing unit for software-controlled execution of functions;
a memory unit for storing calculation data in a number format; and
a model calculation unit for calculating a data-based function model in a control unit, including:
a processor core configured to carry out a strictly hardware-based calculation of an algorithm for a data-based function model, the data-based function model being calculated using provided calculation data; and
a strictly hardware-based conversion unit configured to provide the processor core with at least a portion of the calculation data in a predefined number format.

14. The control unit of claim 13, wherein the main processing unit provides a selection signal to the model calculation unit as a function of the number format in which calculation data are stored in the memory unit, so that the conversion unit, as a function of the selection signal, carries out a conversion of the calculation data into the predefined number format.

15. The control unit of claim 13, wherein the conversion unit includes at least one conversion block for converting a first number format of data into the predefined number format, as well as a multiplexer, in order, as a function of the selection signal, to forward to the processor core either the provided calculation data or the calculation data converted by one of the at least one conversion blocks into the predefined number format.

16. The control unit of claim 15, wherein the predefined number format corresponds to a 32-bit floating point number format.

17. The control unit of claim 15, wherein a first conversion block is configured to convert data from a floating point number format which includes a bit number lower than the predefined number format, into the predefined number format.

18. The control unit of claim 15, wherein a second conversion block is configured to convert data from a fixed point number format into the predefined number format.

19. The control unit of claim 18, wherein the second conversion block is configured to take into account a predefined exponent value when converting data from the fixed point number format into the predefined number format.

20. The control unit of claim 13, wherein the data-based function model include a Gaussian process model.

21. The control unit of claim 13, wherein the calculation data includes hyperparameters and node data.

22. The control unit of claim 13, wherein the at least a portion of the calculation data includes node data.

23. The control unit of claim 13, wherein the calculation data includes hyperparameters and node data, and wherein the at least a portion of the calculation data includes the node data.

24. The control unit of claim 13, wherein the data-based function model include a Gaussian process model, wherein the calculation data includes hyperparameters and node data, and wherein the at least a portion of the calculation data includes the node data.
